(19) United States
(12) Patent Application Publication
(10) Pub. No.: US 2012/0112297 A1
(43) Pub. Date: May 10, 2012

(54) MAGNETIC RANDOM ACCESS MEMORY AND METHOD OF FABRICATING THE SAME

(75) Inventors: Koji YAMAKAWA, Tokyo (JP); Katsuaki NATORI, Kanagawa-ken (JP); Daisuke IKENO, Kanagawa-ken (JP); Yasuyuki SONODA, Kanagawa-ken (JP)

(73) Assignee: KABUSHIKI KAISHA TOSHIBA, Tokyo (JP)

(21) Appl. No.: 13/049,806

(22) Filed: Mar. 16, 2011

(30) Foreign Application Priority Data
Nov. 4, 2010 (JP) 2010-247871

(51) Int. Cl. H01L 29/82; H01L 21/8246

(52) U.S. Cl. 257/421; 438/3; 257/E21.665; 257/E29.323

(57) ABSTRACT

According to one embodiment, a magnetic random access memory including a magneto resistive element, including a free layer including first metal atoms, a first metal layer on the free layer and including a first metal, a first interfacial magnetic layer on the first metal layer, a nonmagnetic layer provided on the first interfacial magnetic layer, a second interfacial magnetic layer on the nonmagnetic layer, a second metal layer on the second interfacial magnetic layer and including a second metal, and a pinned layer provided on the second metal layer and including the second metal atoms.

### CROSS REFERENCE TO RELATED APPLICATION

This application is based upon and claims the benefit of priority from prior Japanese Patent Application No. 2010-247871, filed on Nov. 4, 2010, the entire contents of which are incorporated herein by reference.

### FIELD

Exemplary embodiments described herein generally relate to a magnetic random access memory and a method of fabricating the magnetic random access memory.

### BACKGROUND

Magnetic random access memories (MRAMs) using a tunneling magneto resistive (TMR) effect have been developed in recent years.

Magnetic random access memories use a magneto resistive element which includes a magnetic tunnel junction (MTJ), and thus have a large rate of change in magneto resistance.

For miniaturization and reduction of an electric current of a memory employing a spin injection writing method now under study, a magneto resistive element structure using a perpendicular magnetization film is more suitable than a magneto resistive element structure using a plane magnetization film.

However, the magneto resistive element structure using the perpendicular magnetization film presents a problem that stably operable magnetic random access memories cannot be obtained employing the magneto resistive element whose magnetic characteristics change due to diffusion of atoms in the perpendicular magnetization film into the nonmagnetic layer in the heat treatment in the manufacturing process.

### BRIEF DESCRIPTION OF THE DRAWINGS

FIG. 1 is a cross-sectional view showing a basic structure of a magneto resistive element with perpendicular magnetization according to a first embodiment.

FIG. 2 is a cross-sectional view showing a basic structure of a magneto resistive element with perpendicular magnetization according to the first embodiment.

FIGS. 3A to 3D are cross-sectional views showing a magnetic random access memory according the first embodiment.

FIG. 4 is a cross-sectional view showing a basic structure of a magneto resistive element with perpendicular magnetization according to the first embodiment.

FIGS. 5A and 5B are magnetization curves of the magneto resistive according to the first embodiment.

### DETAILED DESCRIPTION

According to one embodiment, a magnetic random access memory including a magneto resistive element, including a free layer including first metal atoms, a first metal layer on the free layer and including the first metal atoms, a first interfacial magnetic layer on the first metal layer, a nonmagnetic layer provided on the first interfacial magnetic layer, a second interfacial magnetic layer on the nonmagnetic layer, a second metal layer on the second interfacial magnetic layer and including second metal atoms, and a pinned layer provided on the second metal layer and including the second metal atoms.

Embodiments will be described below in detail with reference to the attached drawings mentioned above. Throughout the attached drawings, similar or same reference numerals show similar, equivalent or same components. cl First Embodiment

Descriptions will be herein below provided for a magnetic random access memory of a first embodiment.

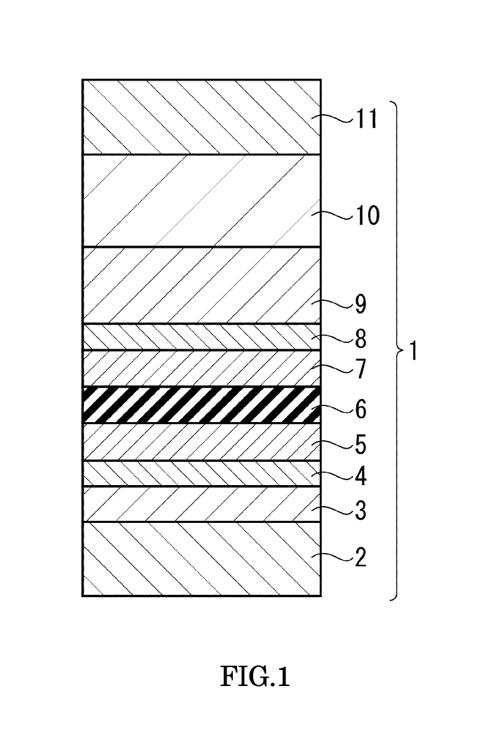

FIG. 1 is a cross-sectional view showing a basic structure of a magneto resistive element 1 of the first embodiment, which has perpendicular magnetization. As shown in FIG. 1, the magneto resistive element 1 includes a lower electrode 2, a free layer 3, a first metal layer 4, a first interfacial magnetic layer 5, a nonmagnetic layer 6, a second interfacial magnetic layer 7, a second metal layer 8, a pinned layer 9, a magnetic field control layer 10 which compensates magnetic field from other magnetic layer and an upper electrode 11.

In the magneto resistive element 1 of the first embodiment, as shown in FIG. 1, the free layer 3 is provided on the lower electrode 2. Pt, Ir, Ru or Cu, for example, is used for the lower electrode 2. The free layer 3 is a perpendicular magnetization film whose magnetization is virtually perpendicular to the film surface, and the magnetization direction is variable. In addition, first metal atoms are included in the free layer 3. The first metal atoms are atoms of Pt, Pd or the like, for example. To put it specifically, an ordered alloy layer is used for the free layer 3. FePd, FePt, CoPt or CoPd, for example, is used for the free layer 3. The film thickness of the lower electrode 2 is approximately 50 Å, for example. The film thickness of the free layer 3 is approximately 10 Å, for example. The lower electrode 2 additionally has a role of serving as a layer for controlling the orientation of the free layer 3 formed on the lower electrode 2.

The first metal layer 4 is provided on the free layer 3. The first metal layer 4 includes at least a metal selected from Ta, Ti, V, Y, Zr and Yb, for example, as well as a first metal. In addition, the first metal layer 4 includes an alloy of these atoms. It should be noted that in the first metal layer 4, the metal may be alloyed fully or partially. Otherwise, the component elements may be partially bonded each other. The film thickness of the first metal layer 4 is approximately 5 Å, for example.

The first interfacial magnetic layer 5 is provided on the first metal layer 4. Co, Fe, CoFe, or CoFeB, for example, is used for the first interfacial magnetic layer 5. The first interfacial magnetic layer 5 has perpendicular magnetization which results from the exchange coupling with the perpendicular magnetization film of the free layer 3 or the like. The film thickness of the first interfacial magnetic layer 5 is approximately 10 Å, for example.

The nonmagnetic layer 6 as a tunneling barrier film is provided on the first interfacial magnetic layer 5. It is desirable that the nonmagnetic layer 6 should be an oxide having a NaCl-structure, and concurrently that a material which makes the lattice mismatch smaller between the (100) plane of the oxide and the first interfacial magnetic layer 5 should be selected for the nonmagnetic layer 6. As the nonmagnetic layer 6, an insulating film preferentially oriented in the [100] direction can be obtained by growing the crystal on an amorphous CoFeB alloy structure, for example. MgO, CaO, SrO, TiO, VO, NbO or the like is used for the nonmagnetic layer 6. However, another material may be used for the nonmagnetic layer 6. The film thickness of the nonmagnetic layer 6 is approximately 10 Å, for example. The resistance value of the magneto resistive element 1 is set to be approximately 10 Ωμm².

The second interfacial magnetic layer 7 is provided on the nonmagnetic layer 6. The second interfacial magnetic layer 7 is composed of the same material as is the first interfacial magnetic layer 5. The second interfacial magnetic layer 7 has perpendicular magnetization which results from the exchange coupling with the perpendicular magnetization film of the pinned layer 9 or the like. The film thickness of the second interfacial magnetic layer 7 is approximately 10 Å, for example.

The second metal layer 8 is provided on the second interfacial magnetic layer 7. The second metal layer 8 includes at least a metal selected from Ta, Ti, V, Y, Zr and Yb, for example, as well as the second metal atoms. In addition, the second metal layer 8 includes an alloy of these metals. The second metal is Pt, Pd or the like. It should be noted that in the second metal layer 8, the metals may be alloyed fully or partially. Otherwise, the component elements may be partially bonded each other. The film thickness of the second metal layer 8 is approximately 5 Å, for example.

The pinned layer 9 is provided on the second metal layer 8. The pinned layer 9 is a perpendicular magnetization film whose magnetization is virtually perpendicular to the film surface. The magnetization direction of the pinned layer 9 is fixed in one direction. In addition, the pinned layer 9 contains the second metal atoms. A disordered alloy, an ordered alloy, an artificial superlattice or the like is used for the pinned layer 9 which is the perpendicular magnetization film. As the disordered alloy, an alloy of Co with an element such as Cr, Ta, Nb, V, W, Hf, Ti, Zr, Pt, Pd, Fe or Ni is used. A CoCr alloy or a CoPt alloy, for example, is used as the disordered alloy. As the ordered alloy, an alloy of Fe, Co or Ni with Pt or Pd is used. FePt, FePd and CoPt, for example, may be mentioned as the ordered alloy. As the artificial superlattice, a lattice obtained by depositing an element of Fe, Co or Ni and an element of Cr, Pt, Pd, Ir, Rh, Ru, Os, Re or Au is used. Otherwise, a lattice obtained by depositing an alloy of the two elements is used as the artificial superlattice. Co/Pd, Co/Pt or Co/Ru, for example, is used as the artificial superlattice. In addition, an alloy material including a transition metal such as Tb, Dy or Gd, that is to say, TbFe, TbCo, DyTbFeCo, TbCoFe or the like may be used for the pinned layer 9. The film thickness of the pinned layer 9 is approximately 60 Å, for example.

The magnetic field control layer 10 is provided on the pinned layer 9. The magnetic field control layer 10 is an antiferromagnetic film provided for the purpose of adjusting a leak magnetic field from the pinned layer 9, suppressing a magnetic influence on the free layer 3, and fixing the magnetization of the pinned layer 9 in a predetermined direction. FeMn, NiMn, PtMn, PdMn, PtPdMn, RuMn, OsMn, IrMn, CrPtMn or the like, which is an alloy of Mn with one selected from Fe, Ni, Pt, Pd, Ru, Os and Ir, for example, is used for the magnetic field control layer 10. The film thickness of the magnetic field control layer 10 is approximately 80 Å, for example.

The upper electrode 11 is provided on the magnetic field control layer 10. A film composed of Ru or Ta, for example, is used as the upper electrode 11. The film thickness of the upper electrode 11 is approximately 50 Å, for example.

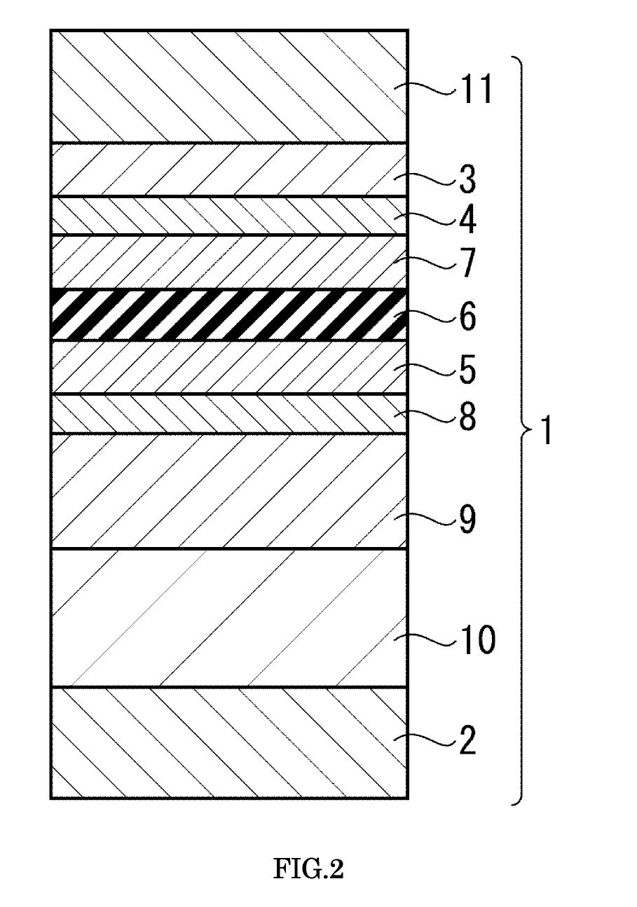

It should be noted that the magnetization of the free layer 3 can be controlled precisely by the structure of the magneto resistive element 1 in which the lower electrode 2, the free layer 3, the first metal layer 4, the first interfacial magnetic layer 5, the nonmagnetic layer 6, the second interfacial magnetic layer 7, the second metal layer 8, the pinned layer 9, the magnetic field control layer 10 and the upper electrode 11 are stacked in an order. Otherwise, the magnetization of the free layer 3 can be controlled precisely, too, by a structure in which, as shown in FIG. 2, the lower electrode 2, the magnetic field control layer 10, the pinned layer 9, the second metal layer 8, the first interfacial magnetic layer 5, the nonmagnetic layer 6, the second interfacial magnetic layer 7, the first metal layer 4, the free layer 3 and the upper electrode 11 are stacked in an order.

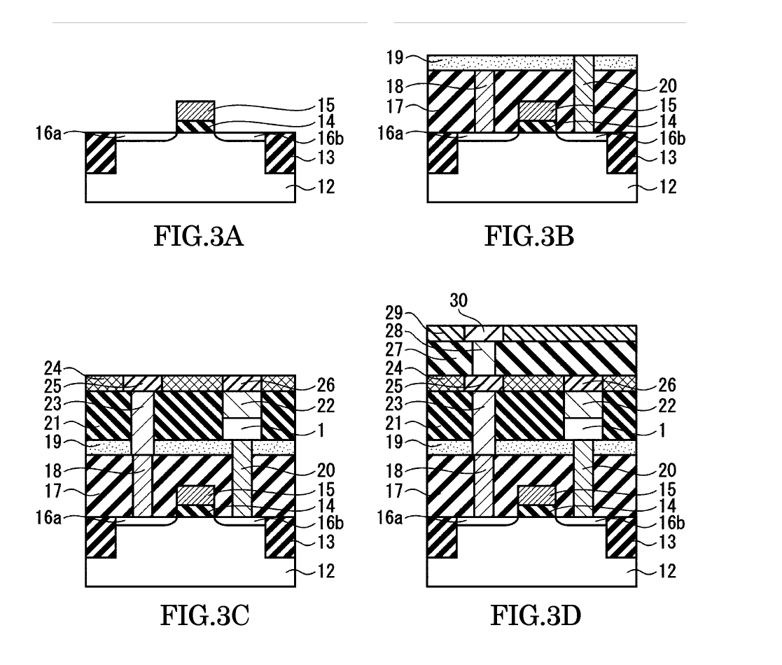

Next, a method of manufacturing a magnetic random access memory of the first embodiment will be described by using FIG. 3.

As shown in FIG. 3A, an STI (Shallow Trench Isolation) structure is formed by forming isolation grooves in a semiconductor substrate 12, and subsequently embedding isolation insulators 13, for example, silicon oxide films in the respective isolation grooves. Thereafter, a gate insulating film 14 and a gate electrode 15 are formed. After that, a source area 16a and a drain area 16b are formed by ion implantation. Thereby, a selective transistor is formed.

Subsequently, as shown in FIG. 3B, as a first insulating film 17, a silicon oxide film, for example, is formed by plasma CVD (Chemical Vapor Deposition). Afterward, an opening is formed by lithography and RIE (Reactive Ion Etching) in order, so that the source area 16a can be exposed.

Thereafter, a tungsten film, for example, is formed by sputtering or CVD in an atmosphere with a forming gas for the purpose of forming a first contact plug 18 in the opening. After that, the tungsten film is flattened by CMP (Chemical Mechanical Polishing). Thereby, the first contact plug 18 communicating with the source area 16a is formed in the first insulating film 17. The gate electrode 15 is connected to a word line. The source area 16a is connected to a bit line. The drain area 16b is connected to a lead line which is connected to the magneto resistive element 1.

Subsequently, a CVD nitride film 19 is formed on the first insulating film 17 and the first contact plug 18 by CVD. Thereafter, a contact hole communicating with the drain area 16b is formed, and a tungsten film is formed for the purpose of forming a second contact plug 20. Afterward, the tungsten film is flattened by CMP. Thereby, the second contact plug 20 is formed.

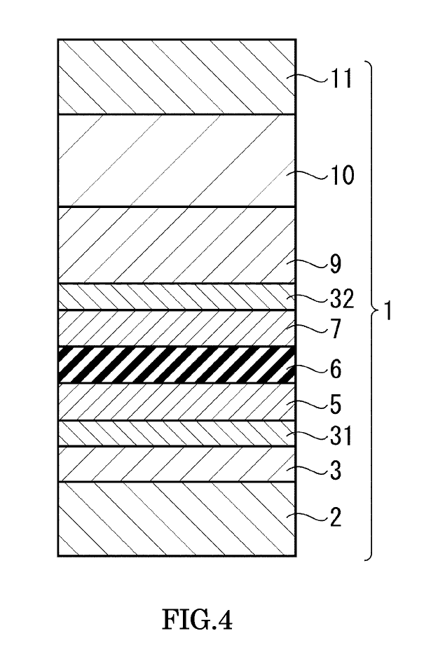

Next, the magneto resistive element 1 is formed. A method of forming the magneto resistive element 1 will be concretely described below by using FIG. 4. As a lower electrode 2, an Ir layer with a film thickness of 50 Å is formed on the second contact plug 20 shown in FIG. 3C. Pt, Ru or Cu is used for the lower electrode 2, instead of Ir.

Subsequently, as a free layer 3, a CoPd layer with a film thickness of 10 Å is formed on the lower electrode 2. Thereafter, as a first diffusion barrier layer 31, a titanium layer with a film thickness of 5 Å is formed on the free layer 3. After that, as a first interfacial magnetic layer 5, an amorphous CoFeB layer with a film thickness of 10 Å is formed on the first diffusion barrier layer 31. In addition, atoms of one selected from Ta, V, Y, Zr and Yb are used for the first diffusion barrier layer 31.

Afterward, as a nonmagnetic layer 6, a tunnel film composed of amorphous MgO with a film thickness of 10 Å is formed on the first interfacial magnetic layer 5. Subsequently, as a second interfacial magnetic layer 7, an amorphous CoFeB layer with a film thickness of 10 Å is formed on the nonmagnetic layer 6.

Thereafter, as a second diffusion barrier layer 32, a titanium layer with a film thickness of 5 Å is formed on the second interfacial magnetic layer 7. Then, as a pinned layer 9, a FePd layer with a film thickness of 60 Å is formed on the second diffusion barrier layer 32. In addition, atoms of one selected from Ta, V, Y, Zr and Yb are included in the second diffusion barrier layer 32.

Afterward, as a magnetic field control layer 10, a PtMn layer with a film thickness of 80 Å is formed on the pinned layer 9. After that, as an upper electrode 11, a ruthenium layer with a film thickness of 50 Å is formed on the magnetic field control layer 10. In addition, Ta or the like is used for the upper electrode 11.

The magneto resistive element 1 is formed through the foregoing manufacturing process. Incidentally, the sequence of stacking the layers in the magneto resistive element 1 is not limited to the above-mentioned case. The lower electrode 2, the magnetic field control layer 10, the pinned layer 9, the first diffusion barrier layer 31, the first interfacial magnetic layer 5, the nonmagnetic layer 6, the second interfacial magnetic layer 7, the second diffusion barrier layer 32, the free layer 3 and the upper electrode 11 may be stacked in order.

It should be noted that the upper electrode 11 may be formed right on the pinned layer 9 without forming the magnetic field control layer 10. In the foregoing manufacturing process, the lower electrode 2, the free layer 3, the first diffusion barrier layer 31, the first interfacial magnetic layer 5, the nonmagnetic layer 6, the second interfacial magnetic layer 7, the second diffusion barrier layer 32, the pinned layer 9, the magnetic field control layer 10 and the upper electrode 11 are formed by sputtering, for example.

Subsequently, annealing is performed in vacuum at a temperature between 300° C. and 350° C. for approximately one hour. Thereby, MgO used in the nonmagnetic layer 6 is crystallized, and amorphous CoFeB used in the first and second interfacial magnetic layers 5, 7 is turned into crystallized CoFe by annealing. Incidentally, annealing may be performed in a nitrogen atmosphere. Otherwise, as RTA (Rapid Thermal Annealing), lamp annealing may be performed in vacuum at 400° C. for approximately 10 to 30 seconds. During annealing, heat is applied to the magneto resistive element 1. Thus, as the first metal atoms, Pd atoms, for example, are diffused from the free layer 3 into the first diffusion barrier layer 31 formed with a titanium layer, for example, while as the second metal atoms, Pd atoms, for example, are diffused from the pinned layer 9 into the second diffusion barrier layer 32 formed with a titanium layer, for example. Thereby, the first diffusion barrier layer 31 is turned into a first metal layer 4 including an alloy of Ti with Pd, for example, while the second diffusion barrier layer 32 is turned into a second metal layer 8 including an alloy of Ti with Pd, for example.

It should be noted that during the subsequent heat treatment, the first metal layer 4 can inhibit the diffusion of atoms included in the free layer 3 into the nonmagnetic layer 6 in common with the first diffusion barrier layer 31, while the second metal layer 8 can inhibit the diffusion of atoms included in the pinned layer 9 into the nonmagnetic layer 6 in common with the second diffusion barrier layer 32.

A hard mask composed of SiOx, SiN or the like is formed on the structure of the thus-formed magneto resistive element 1 in a way that a portion of the magneto resistive element 1 is leaved on the second contact plug 20. Thereafter, the upper electrode 11, the magnetic field control layer 10, the pinned layer 9, the second diffusion barrier layer 32, the second interfacial magnetic layer 7, the nonmagnetic layer 6, the first interfacial magnetic layer 5, the first diffusion barrier layer 31, the free layer 3 and the lower electrode 2 are processed by lithography and etching such as IBE (Ion Beam Etching) or RIE. During the process described above, when the MgO film, for example, used as the nonmagnetic layer 6 is thin, it is likely that a residue adheres to the side surfaces of the magneto resistive element 1 due to the etching, and a leakage current accordingly arises in the magneto resistive element 1, because the noble metals and the like are used for the magneto resistive element 1. For the reason described above, an angle of the taper for the nonmagnetic layer 6 needs to be controlled. It is desirable that the angle of the taper should be 80 degrees or larger. It is particularly desirable that the angle of the taper should be 85 degrees or larger.

Subsequently, an oxygen or hydrogen diffusion barrier layer (not illustrated) is formed by ALD (Atomic Layer Deposition), CVD, or PVD (Physical Vapor Deposition). A film composed of SiN, AlOx or the like is used for the barrier layer.

Thereafter, as shown in FIG. 3C, as a second insulating film 21, a silicon oxide film, for example, is formed on the nitride film 19 formed by CVD in a way that the magneto resistive element 1 is covered with the second insulating film 21.

Afterward, a third contact plug 22 connected to the upper electrode 11 of the magneto resistive element 1 and a fourth contact plug 23 connected to the first contact plug 18 are formed. The third contact plug 22 and the fourth contact plug 23 are formed by processing the second insulating film 21 by lithography and RIE, thus forming the respective contact holes, thereafter embedding Al in the contact holes, and subsequently performing CMP.

After that, a first oxide film 24 is formed on the second insulating film 21, the third contact plug 22 and the fourth contact plug 23. Afterward, the first oxide film 24 is processed by lithography and RIE in a way that the third contact plug 22 and the fourth contact plug 23 are exposed. Thereby, grooves in which to form first wirings 25, 26 are formed in the first oxide film 24. Thereafter, the first wirings 25, 26 are formed by embedding Al in the grooves, and subsequently performing CMP.

After that, a third insulating film 27 is formed on the first oxide film 24 and the first wirings 25, 26 as shown in FIG. 3D. Moreover, the third insulating film 27 is processed by lithography and RIE in a way that the first wiring 25 is exposed. Thereby, a via hole is formed. Thereafter, a via plug 28 is formed by embedding Al in the via hole, and subsequently performing CMP.

After that, a second oxide film 29 is formed on the third insulating film 27 and the via plug 28. Afterward, the second oxide film 29 is processed by lithography and RIE in a way that the via plug 28 is exposed. Thereby, a groove is formed. Thereafter, the second wiring 30 is formed by embedding Al in the groove, and subsequently performing CMP.

It should be noted that instead, a Cu wiring may be formed by a damascene process. In this case, the wiring is formed by forming a barrier film composed of SiN, Ta, TaN, Ru, Cu or the like and a seed layer, as well as subsequently embedding Cu in the groove by Cu plating. Thereby, the magnetic random access memory is formed.

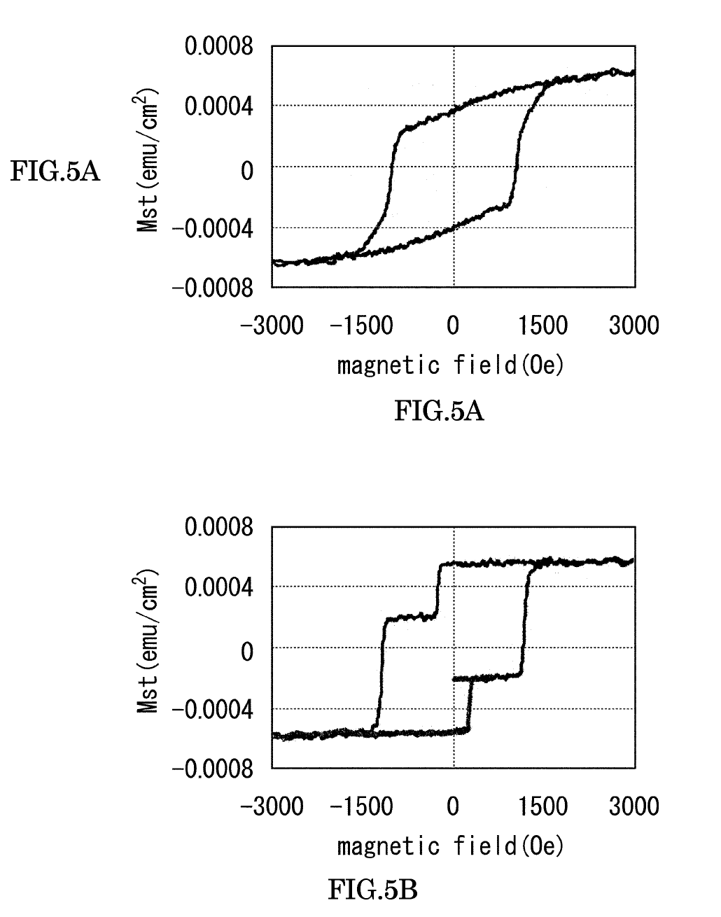

For each of a structure of the magneto resistive element 1 provided with neither the first metal layer 4 nor the second metal layer 8 and a structure of the magneto resistive element 1 provided with the first metal layer 4 and the second mental layer 8, the magnetization characteristics are measured by applying a magnetic field to the magneto resistive element 1 in a perpendicular direction by use of a vibrating sample magnetometer (VSM) after the structure of the magneto resistive element 1 is thermally treated at 350° C. for 30 minutes. In FIGS. 5A and 5B, the horizontal axis represents intensity of the external magnetic field applied to the magneto resistive element, while the vertical axis represents strength of the magnetization in the magneto resistive element. In the structure provided with neither the first metal layer 4 nor the second metal layer 8, as shown in FIG. 5A, the intensity of the magnetic field needed to reverse the magnetization of the free layer 3 has a large variation, and the magnetization characteristics is deteriorated. On the other hand, in the structure provided with the first metal layer 4 and the second metal layer 8 of the embodiment, as shown in FIG. 5B, the intensity of the magnetic field needed to reverse the magnetization of the free layer 3 retains constant, and no conspicuous deterioration is observed as the magnetic characteristics. That is because the first diffusion barrier layer 31 inhibits the diffusion of Pd atoms from the free layer 3 into the nonmagnetic layer 6 while the second diffusion barrier layer 32 inhibits the diffusion of Pd atoms from the pinned layer 9 into the nonmagnetic layer 6. On that occasion, Pd atoms as the first metal atoms diffusing from the free layer 3 and Ti atoms included in the first diffusion barrier layer 31 are formed as the alloy, while Pd atoms as the second metal atoms diffusing from the pinned layer 9 and Ti atoms included in the second diffusion barrier layer 32 are formed as the alloy. Thereby, the evaluation of the electric characteristics of the structure of the embodiment yields a result in which the RA value is 10 Ωcm², the magneto resistive (MR) ratio is 100% or larger.

As described above, according to the first embodiment, the first metal layer 4 is formed by alloying the first metal atoms diffusing from the free layer 3 and the atoms included in the first diffusion barrier layer 31, as well as concurrently, the second metal layer 8 is formed by alloying the second metal atoms diffusing from the pinned layer 9 and the atoms included in the second diffusion barrier layer 32 by using the heat treatment, respectively. Thereby, it is possible to obtain the magneto resistive element 1 in which the diffusing atoms from the free layer 3 and the pinned layer 9 are not diffused into the nonmagnetic layer 6, and which is capable of stably operating even after the heat treatment.

It should be noted that, although the first embodiment has been described on the prerequisite that the first metal layer 4 and the second metal layer 8 are provided, however, one of the first metal layer 4 and the second metal layer 8 may not be provided. In this case, the steps needed to manufacture the magnetic random access memory are reduced in number, and the costs can be accordingly reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic random access memory comprising a magneto resistive element, comprising:
a free layer including first metal atoms;
a first metal layer provided on the free layer, and including a first metal;
a first interfacial magnetic layer provided on the first metal layer;
a nonmagnetic layer provided on the first interfacial magnetic layer;
a second interfacial magnetic layer provided on the nonmagnetic layer;
a second metal layer provided on the second interfacial magnetic layer, and including a second metal; and
a pinned layer provided on the second metal layer, and including a second metal.

2. The magnetic random access memory of claim 1, further comprising:
a magnetic field control layer provided on a surface of the pinned layer, the surface being opposite to a surface of the pinned layer on which the second metal layer is provided.

3. The magnetic random access memory of claim 1, wherein
each of the first metal layer and the second metal layer includes an element selected from Ta, Ti, V, Y, Zr and Yb.

4. The magnetic random access memory of claim 1, wherein
the first metal atoms are composed of an element selected from Pt and Pd, and the second metal atoms are composed of an element selected from Pt and Pd.

5. The magnetic random access memory of claim 1, wherein
at least a part of the metal of the element and at least a part of the first metal are alloyed in the first metal layer, while at least a part of the metal of the element and at least a part of the second metal are alloyed in the second metal layer.

6. The magnetic random access memory of claim 1, wherein
the nonmagnetic layer is an oxide having a NaCl structure, and is composed of at least one selected from MgO, CaO, SrO, TiO, VO and NbO.

7. The magnetic random access memory of claim 1, wherein
the pinned layer is composed of at least one selected from a disordered alloy, an ordered alloy and an artificial superlattice.

8. A magnetic random access memory comprising a magneto resistive element, comprising:
a pinned layer including second metal atoms;
a second metal layer provided on the pinned layer, and including a second metal;
a first interfacial magnetic layer provided on the second metal layer;
a nonmagnetic layer provided on the first interfacial magnetic layer;
a second interfacial magnetic layer provided on the nonmagnetic layer;
a first metal layer provided on the second interfacial magnetic layer, and including a first metal; and
a free layer provided on the first metal layer, and including the first metal atoms.

9. The magnetic random access memory of claim 8, further comprising:
a magnetic field control layer provided on a surface of the pinned layer, the surface being opposite to a surface of the pinned layer on which the second metal layer is provided.

10. The magnetic random access memory of claim 8, wherein
each of the first metal layer and the second metal layer include an element selected from Ta, Ti, V, Y, Zr and Yb.

11. The magnetic random access memory of claim 8, wherein
the first metal are composed of an element selected from Pt and Pd, and the second metal atoms are composed of an element selected from Pt and Pd.

12. The magnetic random access memory of claim 8, wherein
at least a part of the metal of the element and at least a part of the first metal are alloyed in the first metal layer, while at least a part of the metal of the element and at least a part of the second metal are alloyed in the second metal layer.

13. The magnetic random access memory of claim 8, wherein
the nonmagnetic layer is an oxide having a NaCl structure, and is composed of at least one selected from MgO, CaO, SrO, TiO, VO and NbO.

14. The magnetic random access memory of claim 8, wherein
the pinned layer is composed of at least one selected from a disordered alloy, an ordered alloy and an artificial superlattice.

15. A method of fabricating a magnetic random access memory comprising a magneto resistive element, comprising:
forming a free layer;
forming a first diffusion barrier layer on the free layer:
forming a first interfacial magnetic layer on the first diffusion barrier layer;
forming a nonmagnetic layer on the first interfacial magnetic layer;
forming a second interfacial magnetic layer on the nonmagnetic layer;
forming a second diffusion barrier layer on the second interfacial magnetic layer; and
forming a pinned layer on the second diffusion barrier layer,
wherein an alloy of the first metal atoms diffusing from the free layer with atoms included in the first diffusion barrier layer and an alloy of the second metal atoms diffusing from the pinned layer with atoms included in the second diffusion barrier layer are formed by using a heat treatment so as to form a magneto resistive element layer.

16. The method of claim 15, further comprising:
etching the magneto resistive element layer selectively so as to form the magneto resistive element after the heat treatment.

17. The method of claim 16, wherein
a taper angle is formed to the nonmagnetic layer in etching the magneto resistive element layer selectively.

18. The method of claim 17, wherein
the taper angle is set in 80-85 degrees.

19. The method of claim 16, further comprising:
forming a third diffusion barrier layer on the magneto resistive element after etching the magneto resistive element layer selectively.
